(19) United States
(12) Patent Application Publication
(10) Pub. No.: US 2025/0185378 A1
(43) Pub. Date: Jun. 5, 2025

(54) SEMICONDUCTOR DEVICE AND METHOD FOR FORMING THE SAME

(71) Applicants: TAIWAN SEMICONDUCTOR MANUFACTURING COMPANY, LTD., HSINCHU (TW); NATIONAL TAIWAN UNIVERSITY, TAIPEI (TW)

(72) Inventors: Jih-Chao Chiu, New Taipei City (TW); Eknath Sarkar, New Taipei City (TW); Yuan-Ming Liu, Taichung City (TW); Chee-Wee Liu, Taipei City (TW)

(73) Assignees: TAIWAN SEMICONDUCTOR MANUFACTURING COMPANY, LTD., HSINCHU (TW); NATIONAL TAIWAN UNIVERSITY, TAIPEI (TW)

(21) Appl. No.: 18/525,579

(22) Filed: Nov. 30, 2023

(51) Int. Cl. H01L 29/66; H01L 21/02; H01L 21/383; H01L 21/477; H01L 29/06; H01L 29/423; H01L 29/775; H01L 29/786

(52) U.S. Cl. CPC H10D 99/00; H01L 21/02565; H01L 21/02603; H01L 21/383; H01L 21/477; H10D 30/43; H10D 30/6735; H10D 30/6755; H10D 62/121

(57) ABSTRACT

A method includes forming a stack of alternating oxide semiconductor channel layers and sacrificial layers over a substrate; removing first portions of the sacrificial layers to expose channel regions of the oxide semiconductor channel layers; forming a gate structure wrapping around each of the channel regions of the oxide semiconductor channel layers; removing second portions of the sacrificial layers to expose source/drain regions of the oxide semiconductor channel layers; and forming source/drain electrodes wrapping around and in contact with each of the source/drain regions of the oxide semiconductor channel layers, wherein the source/drain electrodes are made of a metal-containing material.

### BACKGROUND

The semiconductor integrated circuit (IC) industry has experienced rapid growth. Technological advances in IC materials and design have produced generations of ICs. Each generation has smaller and more complex circuits than the previous generation. However, these advances have increased the complexity of processing and manufacturing ICs. In the course of IC evolution, functional density (i.e., the number of interconnected devices per chip area) has generally increased while geometric size (i.e., the smallest component (or line) that can be created using a fabrication process) has decreased. This scaling-down process generally provides benefits by increasing production efficiency and lowering associated costs. However, since feature sizes continue to decrease, fabrication processes continue to become more difficult to perform. Therefore, it is a challenge to form reliable semiconductor devices at smaller and smaller sizes.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1 to 14D illustrate a method in various stages of forming a semiconductor device in accordance with some embodiments of the present disclosure.

FIG. 15 illustrates a method of forming a semiconductor device in accordance with some embodiments of the present disclosure.

FIGS. 16A to 17C illustrate a method in various stages of forming a semiconductor device in accordance with some embodiments of the present disclosure.

FIGS. 18 to 22 illustrate a method in various stages of forming a semiconductor device in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced or varied with the down-scaling of the integrated circuits.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, is otherwise obtainable using a single, direct pitches smaller than what is otherwise photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

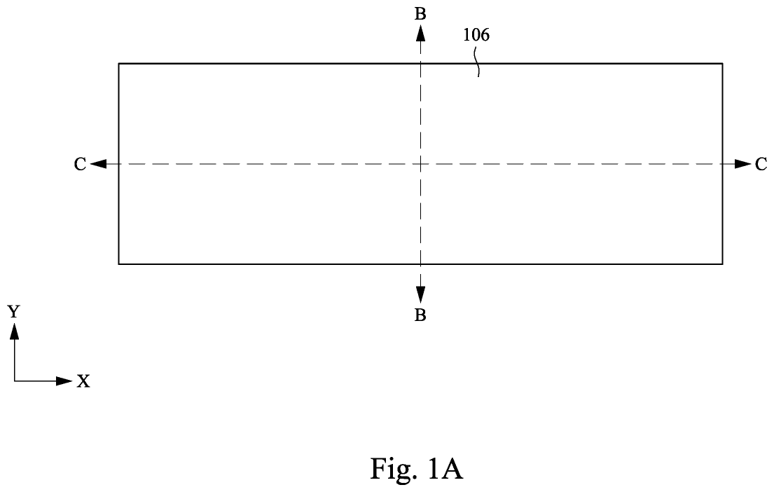

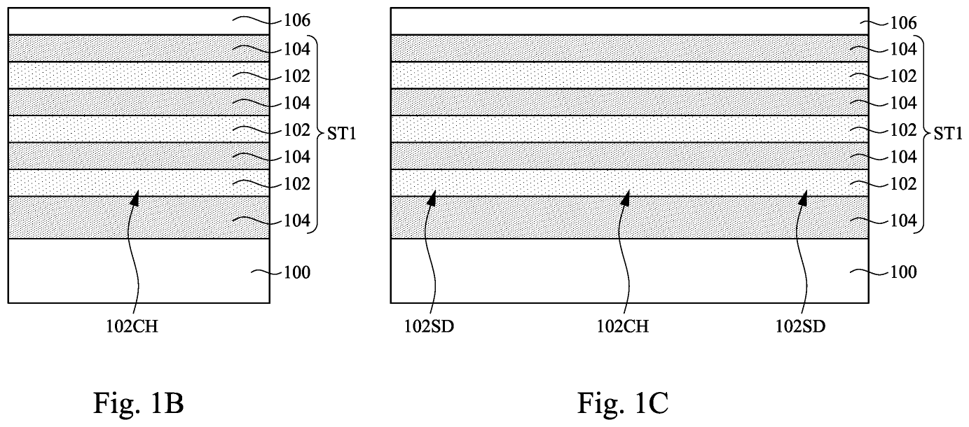

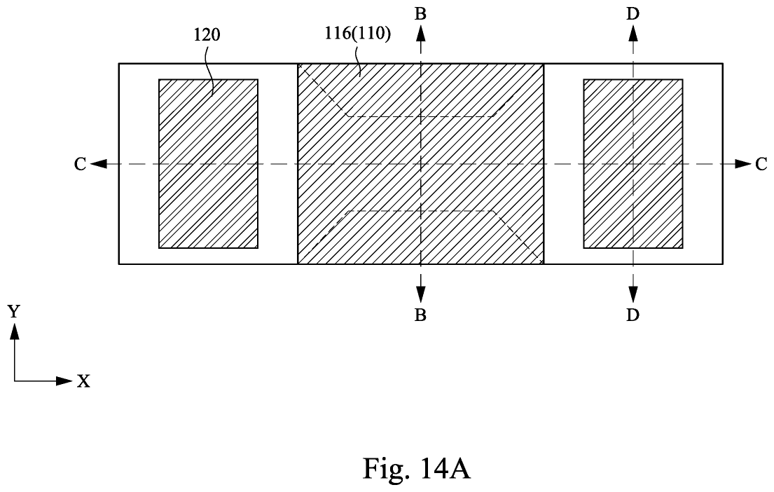

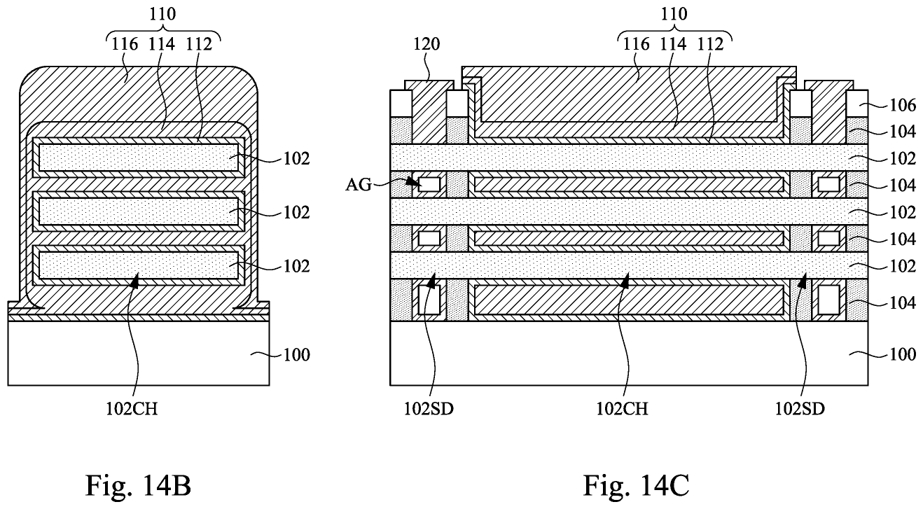

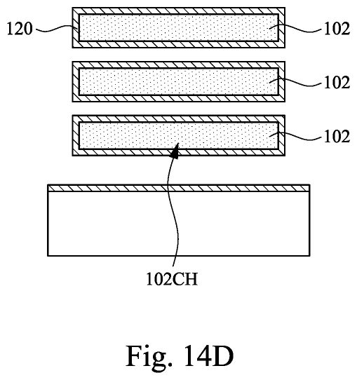

FIGS. 1 to 14C illustrate a method in various stages of forming a semiconductor device in accordance with some embodiments of the present disclosure. In greater detail, FIGS. 1A to 14A are top view of a semiconductor device. FIGS. 1B to 14B are cross-sectional views along line B-B of FIGS. 1A to 14A, respectively. FIGS. 1C to 14C are cross-sectional views along line C-C of FIGS. 1A to 14A, respectively. FIG. 14D is a cross-sectional view along line D-D of FIG. 14A. Although FIGS. 1 to 14C are described as a series of acts, it will be appreciated that these acts are not limiting in that the order of the acts can be altered in other embodiments, and the methods disclosed are also applicable to other structures. In other embodiments, some acts that are illustrated and/or described may be omitted in whole or in part.

Reference is made to FIGS. 1A, 1B, and 1C. Shown there is a substrate 100. Generally, the substrate 100 may include a bulk semiconductor substrate or a silicon-on-insulator (SOI) substrate. An SOI substrate includes an insulator layer below a thin semiconductor layer that is the active layer of the SOI substrate. The semiconductor of the active layer and the bulk semiconductor generally include the crystalline semiconductor material silicon, but may include one or more other semiconductor materials such as germanium, silicon-germanium alloys, compound semiconductors (e.g., GaAs, AlAs, InAs, GaN, AlN, and the like), or their alloys (e.g., GaₓAl₁₋ₓAs, GaₓAl₁₋ₓN, InₓGa₁₋ₓAs and the like), oxide semiconductors (e.g., ZnO, SnO₂, TiO₂, Ga₂O₃, and the like) or combinations thereof. The semiconductor materials may be doped or undoped. Other substrates that may be used include multi-layered substrates, gradient substrates, or hybrid orientation substrates.

A stack ST1 is formed over the substrate 100. The stack ST1 includes alternating channel material layers 102 and sacrificial layers 104. The channel material layers 102 and the sacrificial layers 104 may be formed using deposition process, such as atomic layer deposition (ALD) process, sputtering, plasma-enhanced chemical vapor deposition (PECVD) process, epitaxial growth, or other suitable deposition process. In some embodiments, portions of the sacrificial layers 104 may be removed during the following gate formation process, and portions of the sacrificial layers 104 may be removed during the following source/drain contact formation process. In some embodiments, each of the channel material layers 102 may include a channel region 102CH and source/drain regions 102SD on opposite sides of the channel region 102CH.

In some embodiments, the channel material layers 102 may include oxide semiconductor material, such as indium gallium zinc oxide (IGZO), indium zinc oxide (IZO), zinc oxide (ZnO), indium tin oxide (InSnO), tungsten-doped indium oxide (InWO), gallium oxide (GaOₓ), indium oxide (InOₓ), and the like. In other embodiments, the channel material layers 102 may include semiconductor material, such as silicon (Si), germanium (Ge), silicon germanium (SiGe), germanium tin (GeSn), or the like. In some embodiments, the thickness of each channel material layer 102 is in a range from about 1 nm to about 1000 nm.

The sacrificial layers 104 may include material different from the material of the channel material layers 102 to provide sufficient etching selectivity. In some embodiments where the channel material layers 102 are made of oxide semiconductor material, the sacrificial layers 104 may include dielectric material, such as silicon nitride (SiN), silicon oxide (SiOₓ), or the like. In some embodiments where the channel material layers 102 are made of oxide semiconductor material, the sacrificial layers 104 may also include conductive material, such as titanium nitride (TiN). In some embodiments where the channel material layers 102 are made of semiconductor material, such as silicon or germanium, the sacrificial layers 104 may include silicon germanium (Si₁₋ₓGeₓ). In some embodiments, the thickness of each sacrificial layer 104 is in a range from about 1 nm to about 1000 nm.

A capping layer 106 is formed over the stack ST1. In greater detail, the capping layer 106 is formed in contact with the topmost one of the sacrificial layers 104. In some embodiments, the capping layer 106 may include dielectric material, such as silicon oxide (SiO₂). In some embodiments, the capping layer 106 and the sacrificial layers 104 are made of different materials.

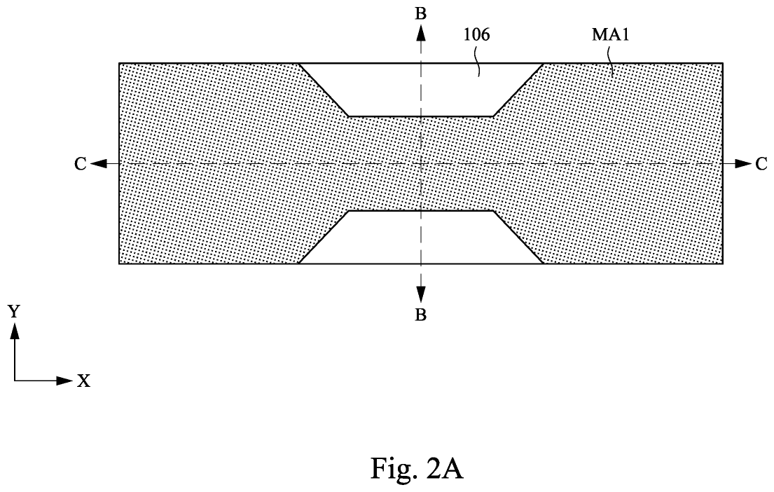

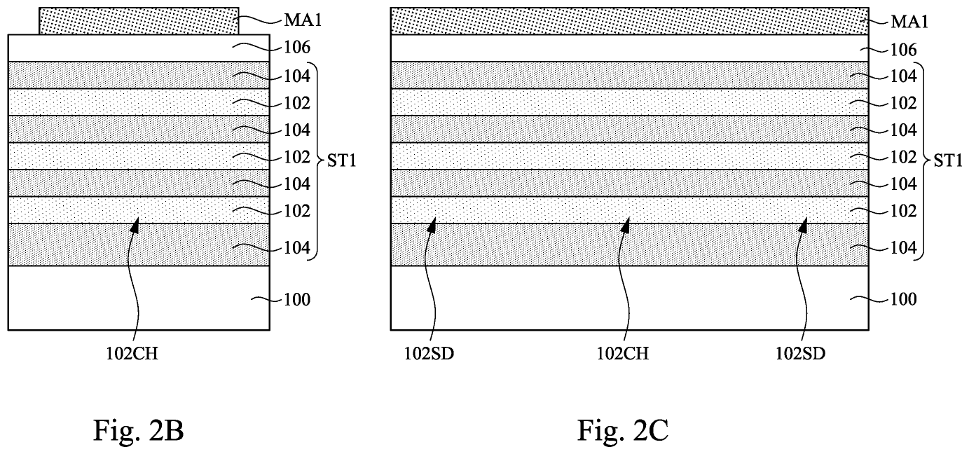

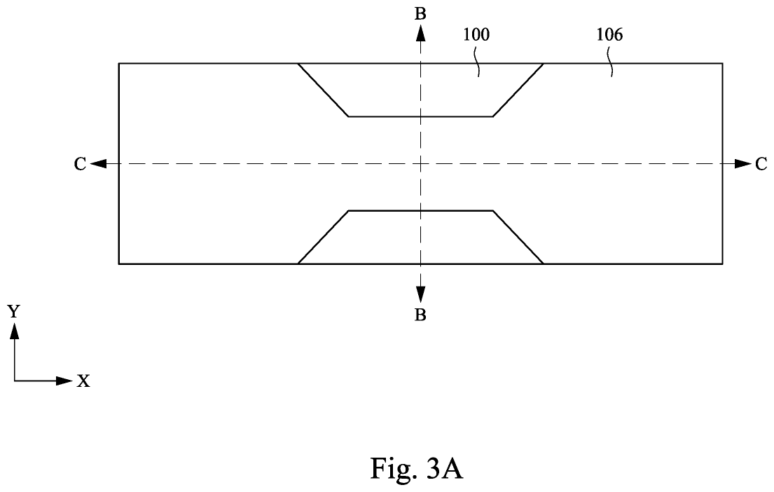

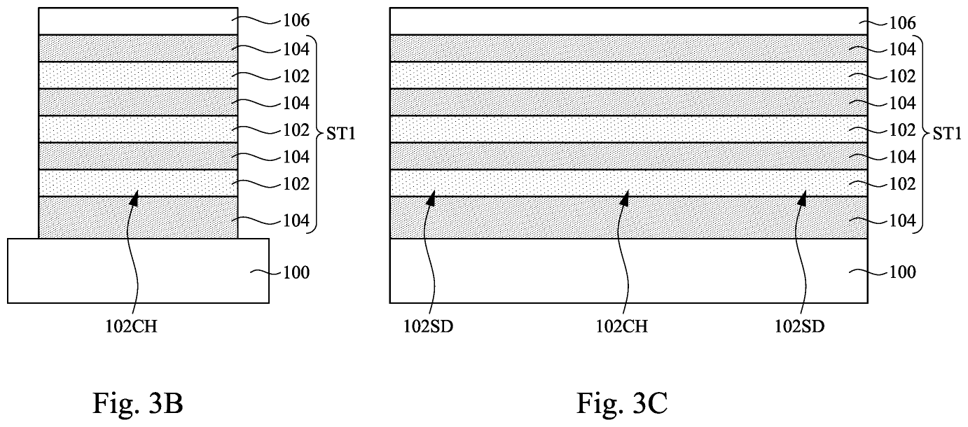

Reference is made to FIGS. 2A, 2B, and 2C. A patterned mask MA1 is formed over the substrate 100. The patterned mask MA1 may include openings that expose portions of the capping layer 106 and the stack ST1, in which such portions will be removed in the following step (see FIGS. 3A to 3C). In some embodiments, the patterned mask MA1 may include photoresist or a hard mask (e.g., silicon nitride), and may be formed by suitable photolithography process.

Reference is made to FIGS. 3A, 3B, and 3C. Portions of the capping layer 106 and the stack ST1 that are exposed through the openings of the patterned mask MA1 are removed. The removal process is performed to define the width of the channel region 102CH of the channel material layers 102 along a first direction (e.g., Y direction). In some embodiments, the portions of the capping layer 106 and the stack ST1 may be removed using suitable etching process, such as wet etch, dry etch, combinations thereof, or the like. After the etching process is complete, the patterned mask MA1 may be removed.

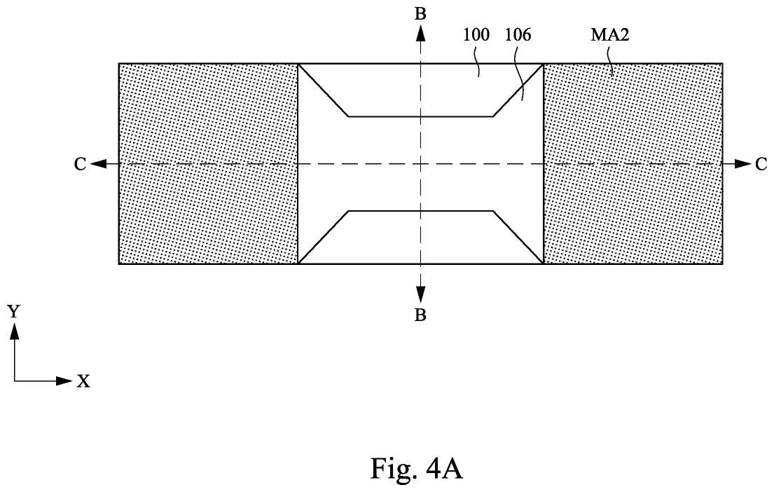

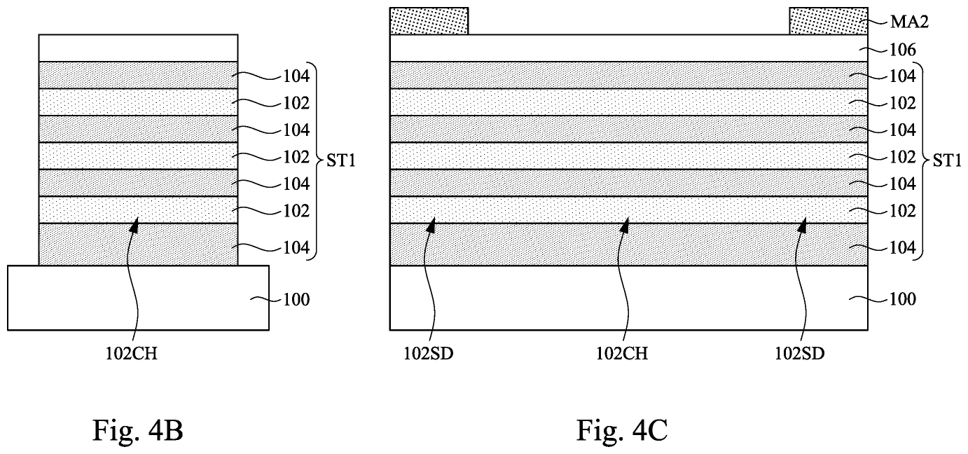

Reference is made to FIGS. 4A, 4B, and 4C. A patterned mask MA2 is formed over the substrate 100. In greater detail, as shown in FIG. 4C, the patterned mask MA2 overlaps the source/drain regions 102SD of the channel material layers 102 along the vertical direction. The patterned mask MA2 may include an opening that expose portions of the capping layer 106 and the stack ST1, in which such portions will be removed in the following step. Specifically, in FIG. 4C, the opening of the patterned mask MA2 may overlap the channel region 102CH of the channel material layers 102 along the vertical direction. In some embodiments, the patterned mask MA2 may include photoresist or a hard mask (e.g., silicon nitride), and may be formed by suitable photolithography process.

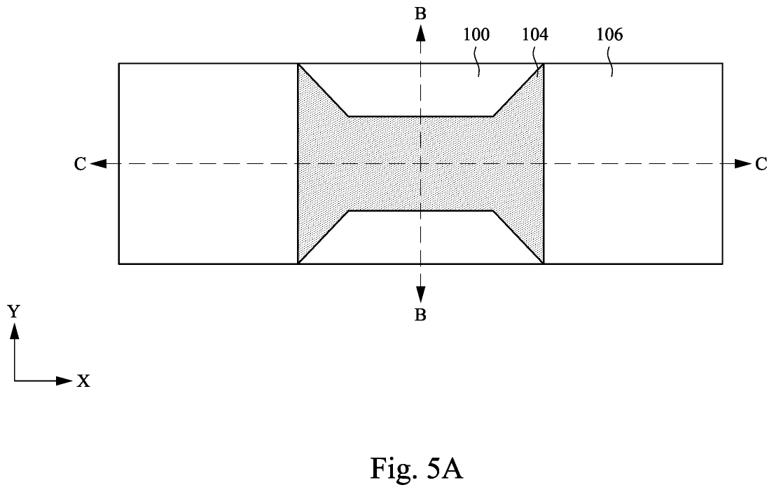

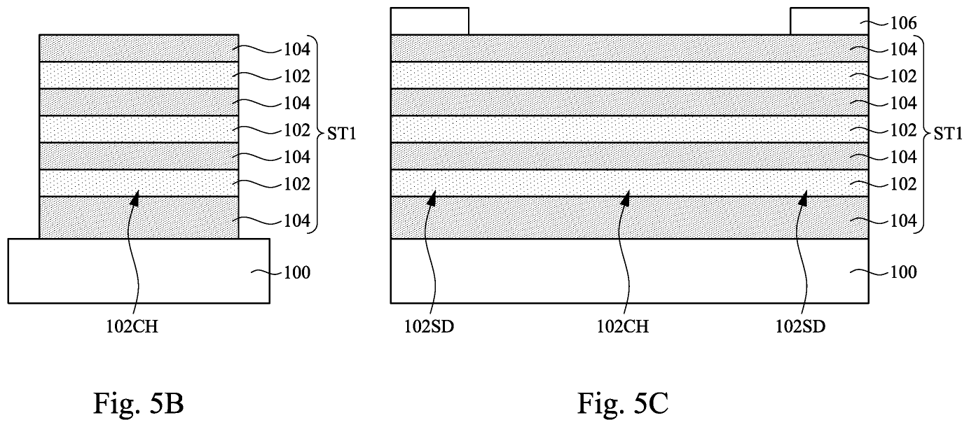

Reference is made to FIGS. 5A, 5B, and 5C. A portion of the capping layer 106 that is exposed through the opening of the patterned mask MA2 is removed, such that top surface of the topmost sacrificial layer 104 is exposed. In some embodiments, the portion of the capping layer 106 may be removed using suitable etching process, such as wet etch, dry etch, combinations thereof, or the like. After the etching process is complete, the patterned mask MA2 may be removed. As shown in FIG. 5C, the remaining portions of the capping layer 106 overlap the source/drain regions 102SD of the channel material layers 102, respectively.

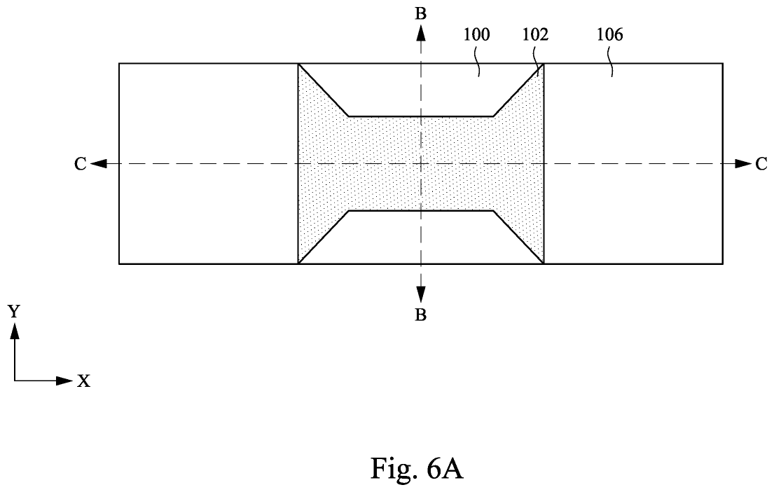

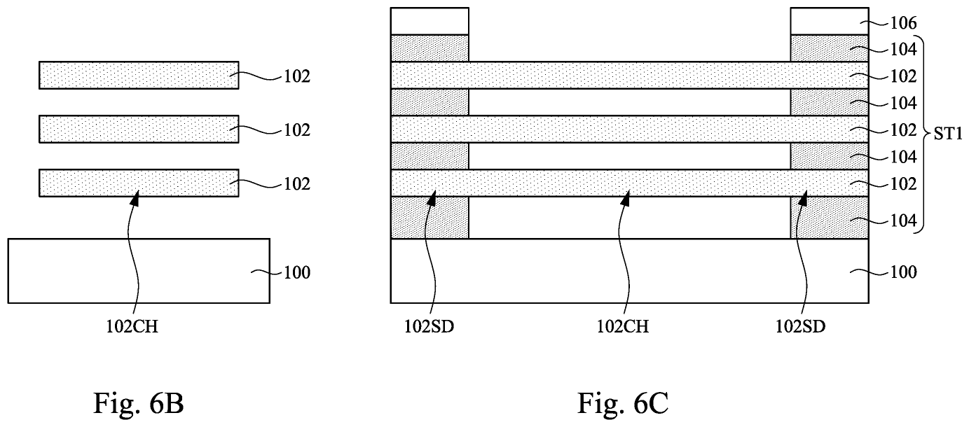

Reference is made to FIGS. 6A, 6B, and 6C. An etching process is performed by using the remaining portions of the capping layer 106 as etching mask, so as to remove portions of the sacrificial layers 104 that are exposed through the remaining portions of the capping layer 106. As a result, the channel regions 102CH of the channel material layers 102 are suspended over the substrate 100. On the other hand, portions of the sacrificial layers 104 that are between adjacent source/drain regions 102SD of the channel material layers 102 may remain after the etching process is complete, because such portions are protected by the capping layer 106 during the etching process. In some embodiments, the etching process may include wet etch, dry etch, combinations thereof, or the like. This process can also be referred to as “channel release process.”

After the channel release process is complete, an oxygen scavenging process may be performed to the source/drain regions 102SD of the channel material layers 102, so as to increase dopant concentration in the source/drain regions 102SD of the channel material layers 102. In greater detail, the oxygen scavenging process is performed to reduce oxygen atomic concentration of the source/drain regions 102SD of the channel material layers 102, so as to generate oxygen vacancies within the source/drain regions 102SD of the channel material layers 102. In some embodiments, the oxygen vacancies can also be regarded as dopants of the source/drain regions 102SD of the channel material layers 102. In some embodiments, the dopant concentration of the source/drain regions 102SD of the channel material layers 102 is higher than the dopant concentration of the channel regions 102CH of the channel material layers 102. That is, oxygen vacancies concentration of the source/drain regions 102SD of the channel material layers 102 is higher than the oxygen vacancies concentration of the channel regions 102CH of the channel material layers 102. Stated another way, oxygen concentration of the source/drain regions 102SD of the channel material layers 102 is lower than the oxygen concentration of the channel regions 102CH of the channel material layers 102. In some embodiments, the doped source/drain regions 102SD of the channel material layers 102 can be referred to as n-type doped regions.

In some embodiments where the channel material layers 102 include oxide semiconductor material, source/drain doped regions can be formed in the source/drain regions 102SD of the channel material layers 102 using the oxygen scavenging process. The oxygen scavenging process may be performed using the remaining portions of the sacrificial layers 104 as oxygen scavenging layers. For example, the sacrificial layers 104 may include a material (e.g., TiN, Ti-containing material, or the like) having higher stronger oxygen affinity than the channel material layers 102. The oxygen scavenging process can be conducted by performing an annealing process having a temperature in a range from about 25° C. to about 500° C. During the annealing process, oxygen atoms in the source/drain regions 102SD of the channel material layers 102 may be attracted by the remaining portions of the sacrificial layers 104, such that oxygen atoms in the source/drain regions 102SD of the channel material layers 102 may diffuse to the sacrificial layers 104, leaving oxygen vacancies in the source/drain regions 102SD of the channel material layers 102. On the other hand, because the portions of the sacrificial layers 104 are removed from the channel regions 102CH of the channel material layers 102, oxygen vacancies may not be formed in the channel regions 102CH of the channel material layers 102. That is, the channel regions 102CH of the channel material layers 102 may not be doped as a result of the annealing process. In some embodiments, the oxygen scavenging process as discussed in FIGS. 6A to 6C may be omitted.

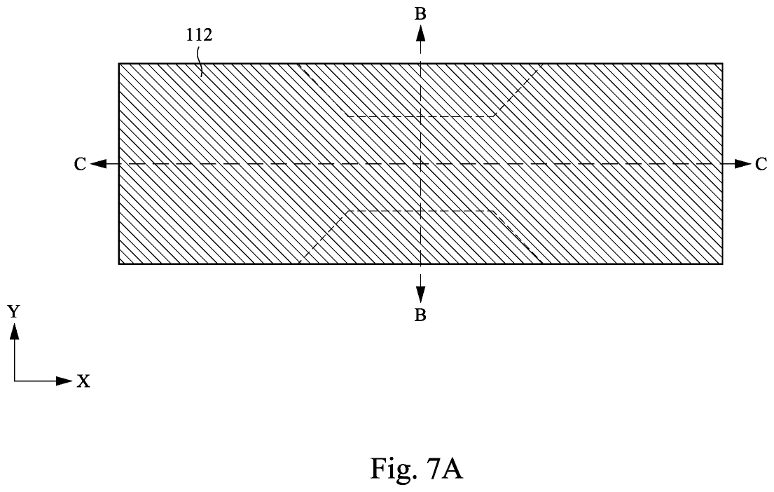

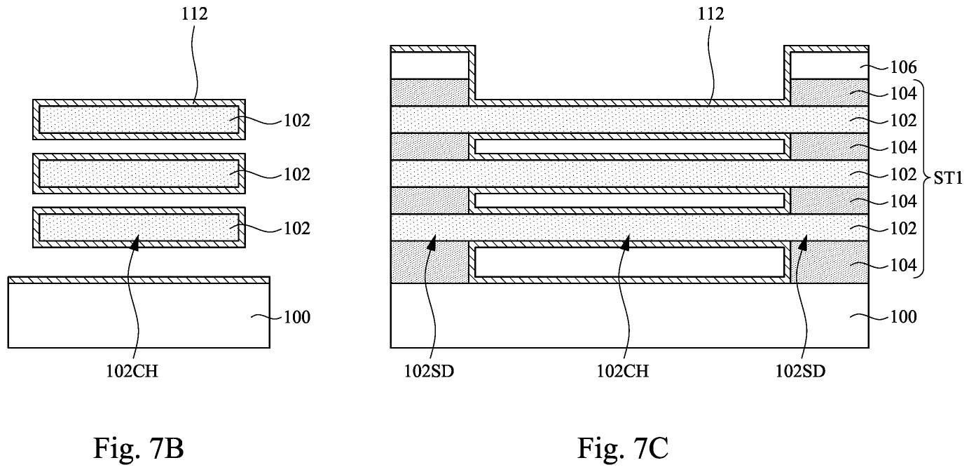

Reference is made to FIGS. 7A, 7B, and 7C. A high-k dielectric layer 112 is deposited over the substrate 100 and wraps around each of the channel regions 102CH of the channel material layers 102. As shown in the cross-sectional view of FIG. 7B, the high-k dielectric layer 112 may be in contact with at least four sides of each of the channel regions 102CH of the channel material layers 102. Examples of high-k dielectric material include aluminum oxide (Al₂O₃), hafnium oxide (HfO₂), titanium oxide (TiO₂), zirconium oxide (ZrO₂), other suitable high-k dielectric materials, and/or combinations thereof. In some embodiments, the high-k dielectric layer 112 is deposited using a conformal deposition process, such as ALD, CVD, or the like. Accordingly, the high-k dielectric layer 112 may also extend to the surfaces of the capping layer 106 and the remaining portions of the sacrificial layers 104. In some embodiments, the thickness of the high-k dielectric layer 112 is in a range from about 1 nm to about 1000 nm.

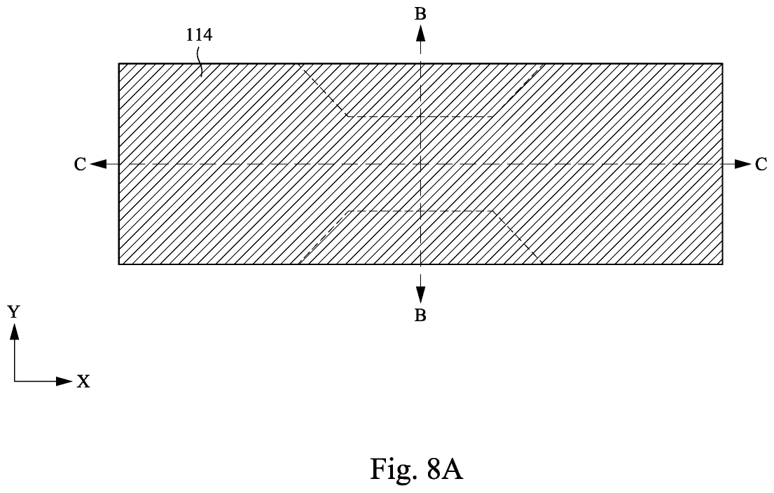

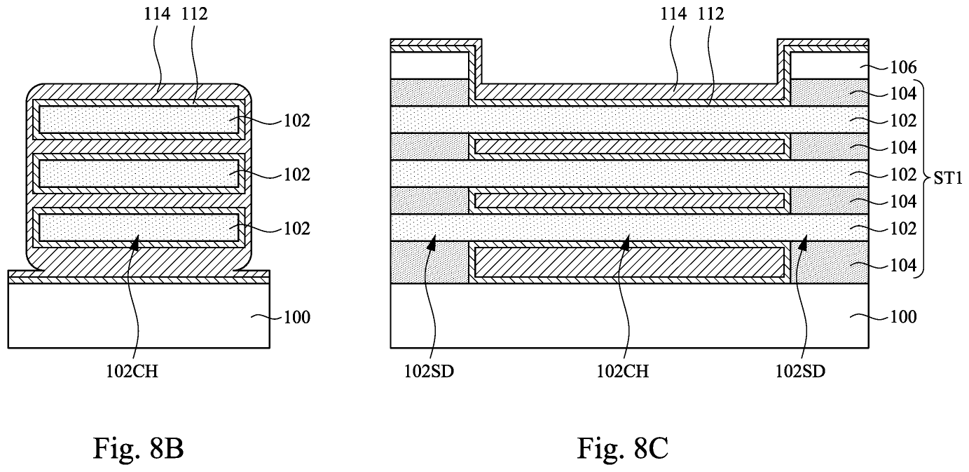

Reference is made to FIGS. 8A, 8B, and 8C. A first gate metal 114 is deposited over the substrate 100 and covering the high-k dielectric layer 112. As shown in the cross-sectional view of FIG. 8B, the first gate metal 114 may be deposited filling the spaces between adjacent two of the channel material layers 102. Similarly, the first gate metal 114 may wrap around each of the channel regions 102CH of the channel material layers 102. In some embodiments, the first gate metal 114 may include titanium nitride (TiN), aluminum (Al), titanium (Ti), or the like. In some embodiments, the first gate metal 114 is deposited using a conformal deposition process, such as ALD, CVD, or the like. Accordingly, the first gate metal 114 may also extend to the surfaces of the capping layer 106. In some embodiments, the thickness of the first gate metal 114 is in a range from about 1 nm to about 1000 nm.

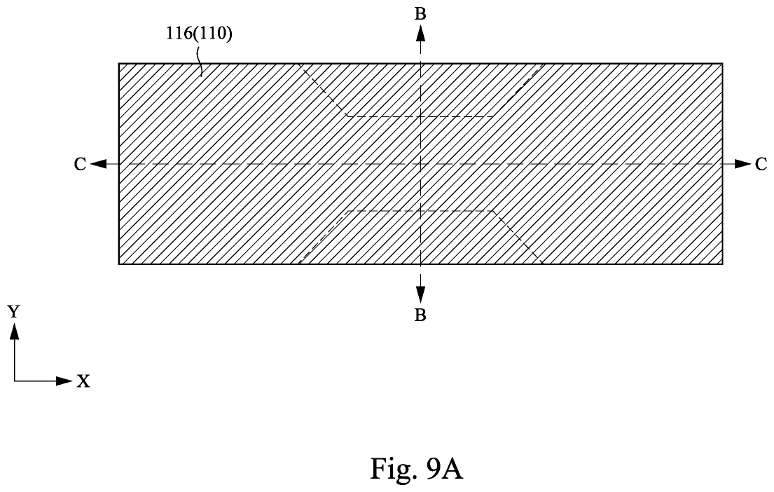

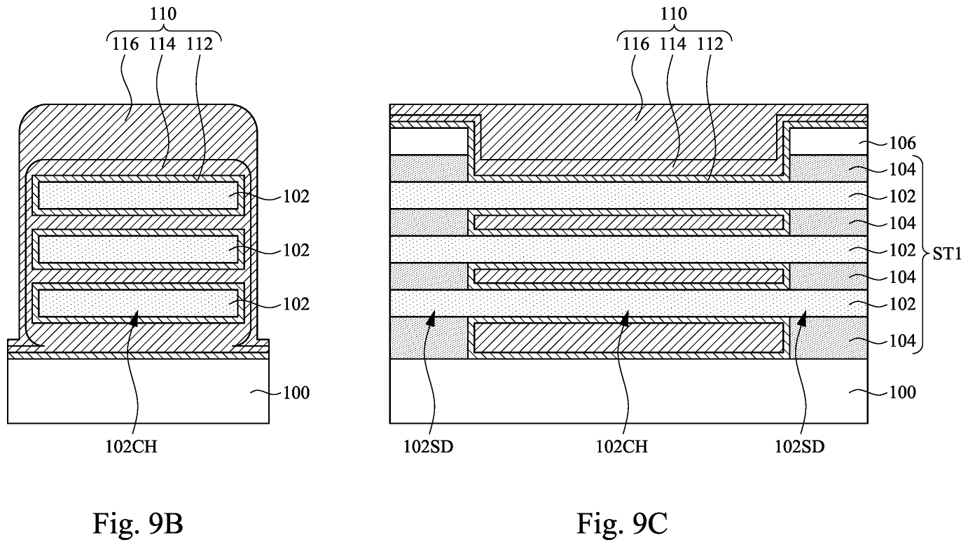

Reference is made to FIGS. 9A, 9B, and 9C. A second gate metal 116 is deposited over the substrate 100 and covering the first gate metal 114. The high-k dielectric layer 112, the first gate metal 114, and second gate metal 116 may collectively be referred to as a gate structure 110. In some embodiments, the second gate metal 116 may include titanium nitride (TiN), aluminum (Al), titanium (Ti), or the like. In some embodiments, the first gate metal 114 and the second gate metal 116 may include a same material, while the first gate metal 114 and the second gate metal 116 are deposited using different deposition process. For example, the first gate metal 114 may be deposited using a conformal deposition process, such as ALD, CVD, or the like. The second gate metal 116 may be deposited using sputtering. In some embodiments, the deposition process of the first gate metal 114 is performed such that the first gate metal 114 is able to warp around the channel material layers 102. The deposition process of the second gate metal 116 is performed to achieve a desired thickness of gate metal. In some embodiments, the thickness of the second gate metal 116 is in a range from about 1 nm to about 1000 nm.

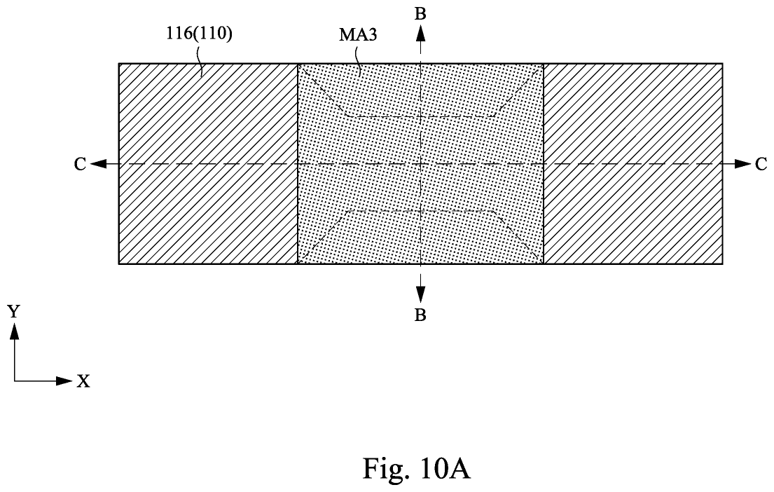

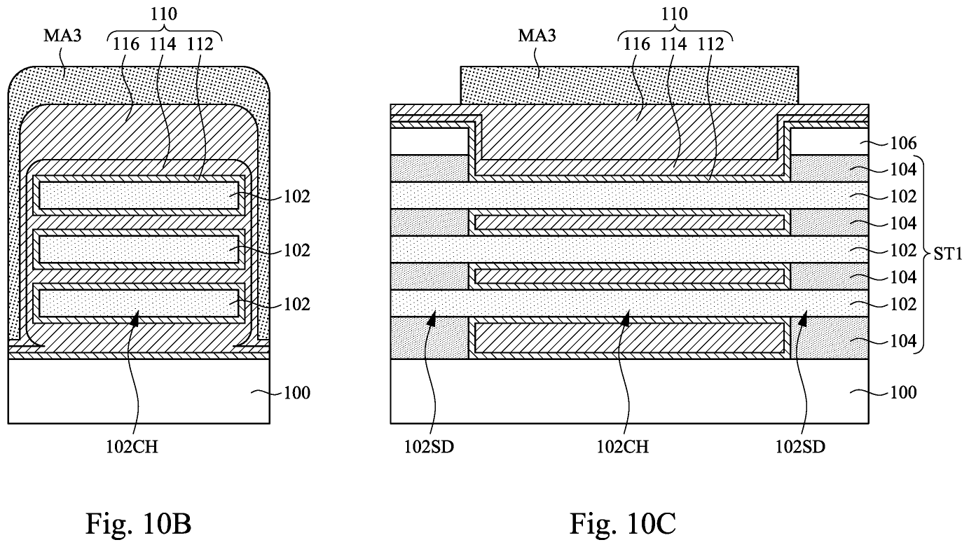

Reference is made to FIGS. 10A, 10B, and 10C. A patterned mask MA3 is formed over the substrate 100. In greater detail, as shown in FIG. 10C, the patterned mask MA3 overlaps the channel regions 102CH of the channel material layers 102 along the vertical direction. The patterned mask MA3 may include openings that expose portions of the capping layer 106 and the stack ST1. Specifically, in FIG. 10C, the opening of the patterned mask MA3 may overlap the source/drain regions 102SD of the channel material layers 102 along the vertical direction. In some embodiments, the patterned mask MA3 may include photoresist or a hard mask (e.g., silicon nitride), and may be formed by suitable photolithography process.

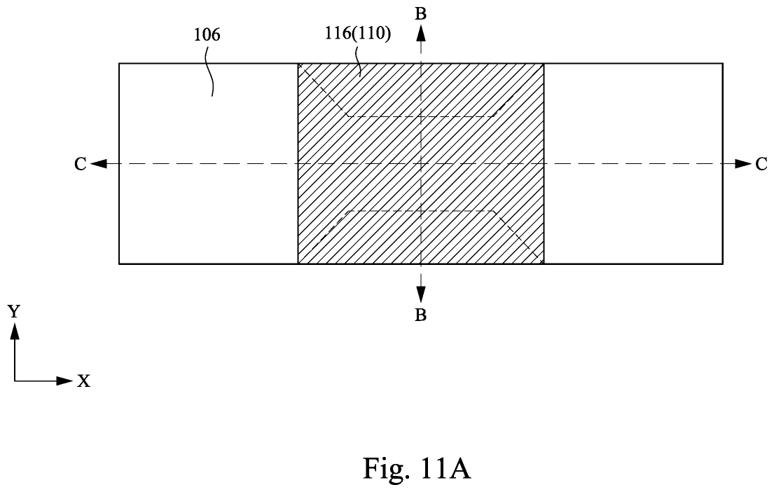

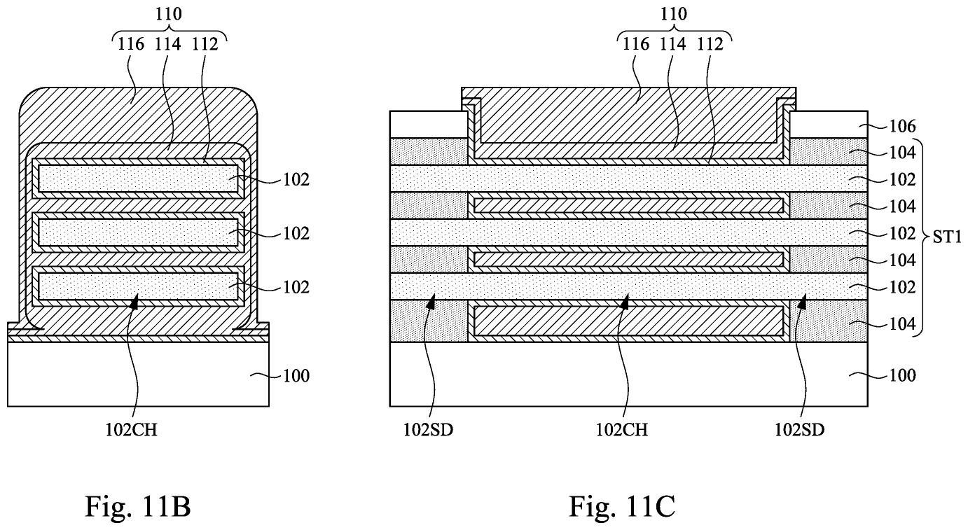

Reference is made to FIGS. 11A, 11B, and 11C. Portions of the gate structure 110 overlapping the source/drain regions 102SD of the channel material layers 102 are removed. As a result, the remaining portion of the gate structure 110 overlaps and wraps around each of the channel regions 102CH of the channel material layers 102. In some embodiments, the portions of the gate structure 110 may be removed using suitable etching process, such as wet etch, dry etch, combinations thereof, or the like. After the etching process is complete, the capping layer 106 is exposed.

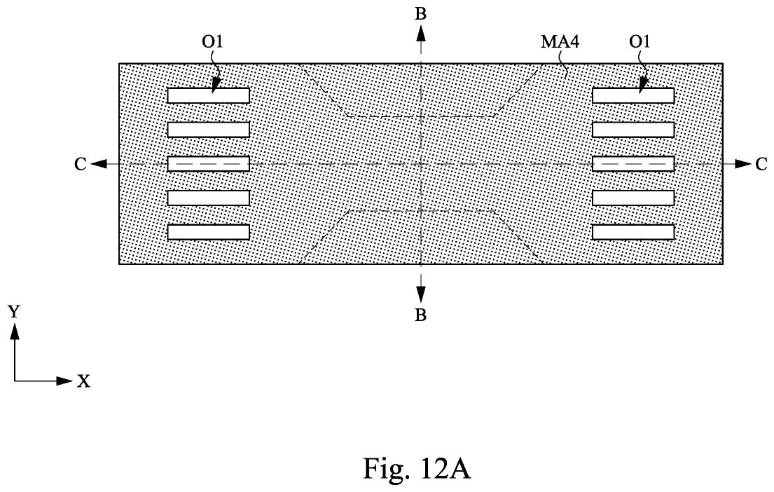

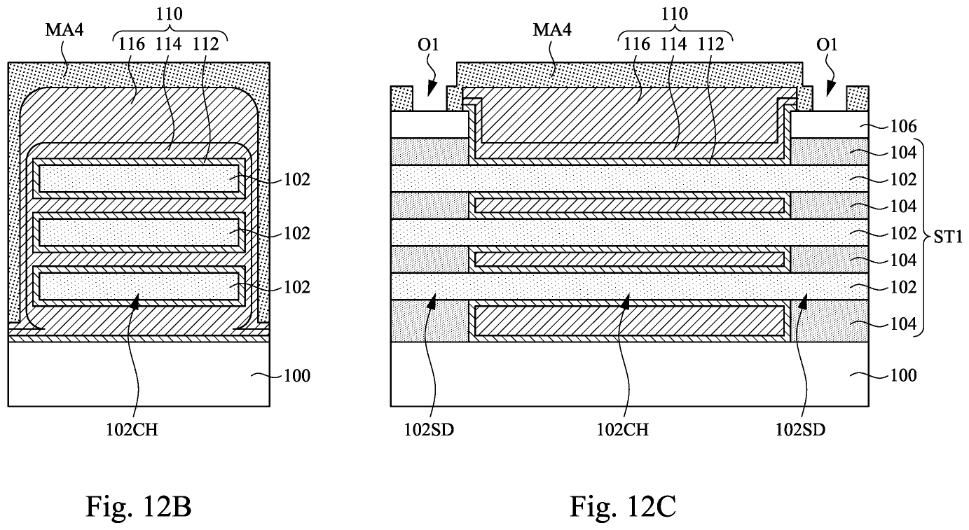

Reference is made to FIGS. 12A, 12B, and 12C. A patterned mask MA4 is formed over the substrate 100. In greater detail, as shown in FIG. 12C, the patterned mask MA4 may include openings O1 that expose portions of the capping layer 106 and the stack ST1. Specifically, in FIG. 12C, the openings O1 of the patterned mask MA4 may overlap the source/drain regions 102SD of the channel material layers 102 along the vertical direction. In some embodiments, the patterned mask MA4 may include photoresist or a hard mask (e.g., silicon nitride), and may be formed by suitable photolithography process.

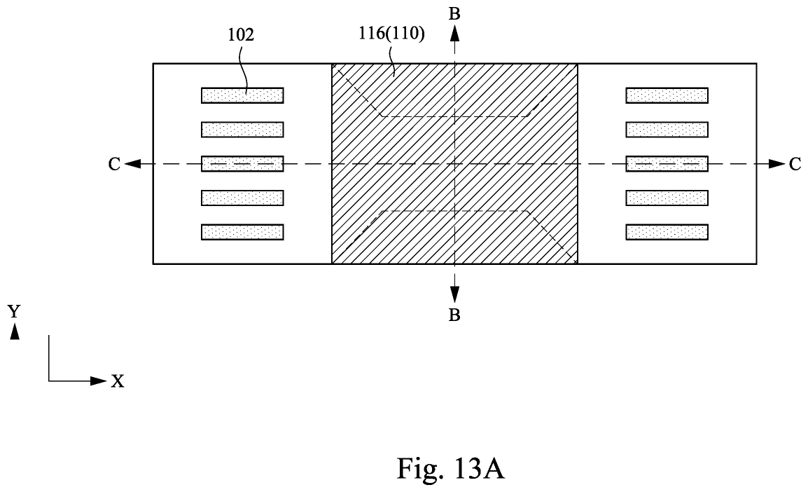

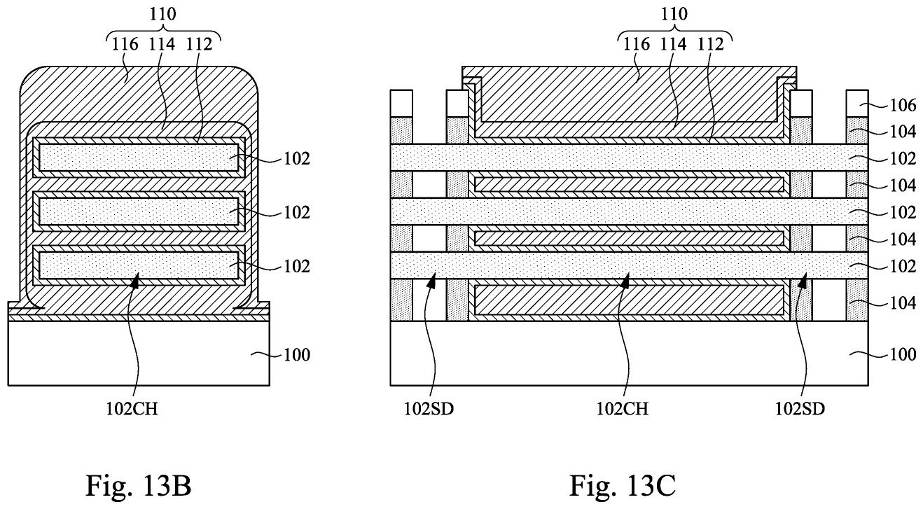

Reference is made to FIGS. 13A, 13B, and 13C. An etching process is performed by using the patterned mask MA4 as etching mask, so as to remove portions of the capping layer 106 and portions of the sacrificial layers 104 that are exposed through the openings O1. As a result, the source/drain regions 102SD of the channel material layers 102 are suspended over the substrate 100. In some embodiments, the etching process may include wet etch, dry etch, combinations thereof, or the like. As shown in FIG. 13C, after the etching process is complete, portions of the sacrificial layers 104 remain on opposite sidewalls of the gate structure 110. The remaining portions of the sacrificial layers 104 may act as inner spacers, and can also be referred to as inner spacers 104 in the following content.

Reference is made to FIGS. 14A, 14B, 14C, and 14D. Source/drain electrodes 120 are formed over the substrate 100 and wrap around each of the source/drain regions 102SD of the channel material layers 102. As shown in the cross-sectional view of FIG. 14D, the source/drain electrodes 120 may be in contact with at least four sides of each of the source/drain regions 102SD of the channel material layers 102. In some embodiments, the source/drain electrodes 120 may include titanium nitride (TiN), aluminum (Al), titanium (Ti), or the like. In some embodiments, the source/drain electrodes 120 may be formed using a conformal deposition process, such as ALD, CVD, or the like. As a result of the conformal deposition process, material of the source/drain electrodes 120 may be sealed at the openings of the capping layer 106, leaving air gaps AG formed within the source/drain electrodes 120. For example, as shown in the cross-sectional view of FIG. 14C, each of the air gaps AG has four sides defined by the source/drain electrodes 120. At least one air gap AG is vertically between adjacent two of the source/drain regions 102SD of the channel material layers 102. At least one air gap AG is vertically between adjacent the source/drain regions 102SD of the bottommost channel material layer 102 and the substrate 100. In some embodiments, the source/drain electrodes 120 are in contact with sidewalls and top surface of the capping layer 106. In some embodiments, the source/drain electrodes 120 are in contact with the sacrificial layers 104.

As mentioned above, the oxygen scavenging process as discussed in FIGS. 6A to 6C may be omitted. Instead, an oxygen scavenging process can be performed after the source/drain electrodes 120 are formed. The oxygen scavenging process is performed to the source/drain regions 102SD of the channel material layers 102, so as to increase dopant concentration in the source/drain regions 102SD of the channel material layers 102. In greater detail, the oxygen scavenging process is performed to reduce oxygen atomic concentration of the source/drain regions 102SD of the channel material layers 102, so as to generate oxygen vacancies within the source/drain regions 102SD of the channel material layers 102. In some embodiments, the oxygen vacancies can also be regarded as dopants of the source/drain regions 102SD of the channel material layers 102.

In some embodiments where the channel material layers 102 include oxide semiconductor material, source/drain doped regions can be formed in the source/drain regions 102SD of the channel material layers 102 using the oxygen scavenging process. The oxygen scavenging process may be performed using the source/drain electrodes 120 as oxygen scavenging layers. For example, the source/drain electrodes 120 may include a material (e.g., TiN, Ti-containing material, or the like) having higher stronger oxygen affinity than the channel material layers 102. During the annealing process, oxygen atoms in the source/drain regions 102SD of the channel material layers 102 may be attracted by the source/drain electrodes 120, such that oxygen atoms in the source/drain regions 102SD of the channel material layers 102 may diffuse to the source/drain electrodes 120, leaving oxygen vacancies in the source/drain regions 102SD of the channel material layers 102.

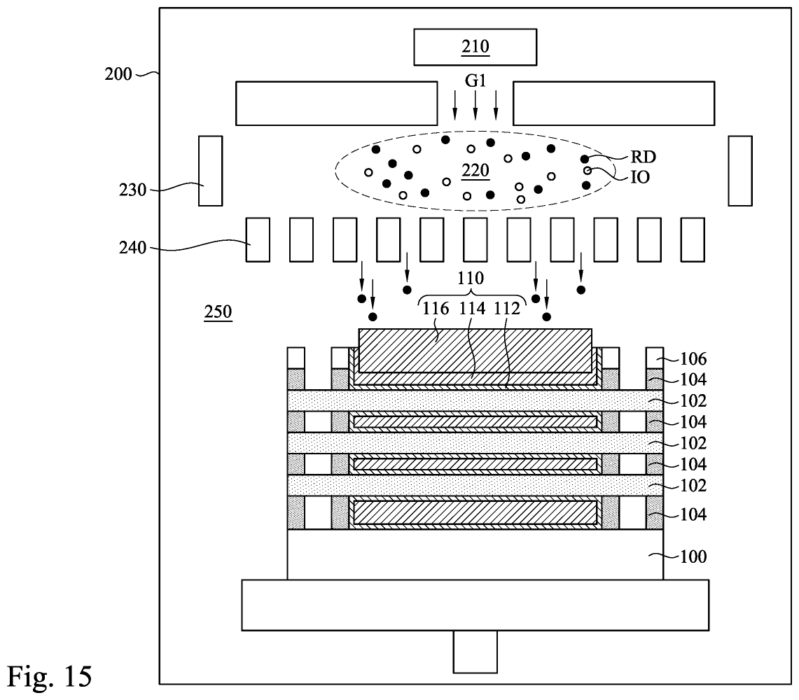

FIG. 15 illustrates a method of forming a semiconductor device in accordance with some embodiments of the present disclosure. The cross-sectional view of FIG. 15 is similar to the cross-sectional view of FIG. 13C, similar elements are labeled the same and relevant details will not be repeated for brevity.

FIG. 15 illustrates a method for forming doped regions in the source/drain regions 102SD of the channel material layers 102. After portions of the sacrificial layers 104 are removed from the source/drain regions 102SD (see FIGS. 13A to 13C), the source/drain regions 102SD of the channel material layers 102 are exposed. Then, the substrate 100 including the structures formed thereon is transferred to a plasma chamber 200. The plasma chamber 200 includes a gas source 210, a plasma generation region 220 in gaseous communication with the gas source 210, a radio frequency (RF) power source 230 adjacent to the plasma generation region 220, an ion filter 240 below the plasma generation region 220, and a reaction chamber 250 below the ion filter 240. The substrate 100 is transferred to the reaction chamber 250 and is supported by a substrate stage.

During the doping process, a gas G1 is supplied into the plasma generation region 220. At the same time, the RF power source 230 may be turn on, so as to generate ion plasma IO and radical plasma RD. In some embodiments, the gas G1 may be fluorine (F)-containing gas, such as nitrogen fluoride (NF₃). The RF power source 230 is configured to generate fluorine ion plasma (F⁻) and fluorine radical plasma (F*). On the other hand, the gas G1 may be hydrogen (H)-containing gas, such as nitrogen fluoride (NF₃). The RF power source 230 is configured to generate hydrogen ion plasma (H⁺) and hydrogen radical plasma (H*). Here, the term “ion” may be referred to as atom or molecule that has a net charge. On the other hand, the term “radical” may be referred to as atom or molecule that has neutral charge.

During the doping process, the ion filter 240 is applied, so as to block certain types of ions in the plasma generation region 220 from entering the reaction chamber 250. The blocking is selective according to ion type. The Ion filter 240 can be operated through electrical or magnetic fields. In some embodiments, the ion filter 240 includes a DC power supply having a variable voltage. For example, when the ion plasma IO and radical plasma RD are fluorine ion plasma (F⁻) and fluorine radical plasma (F*), respectively, the ion filter 240 may be operated to generate a positive electrical field to attract the fluorine ion plasma (F⁻), and thus the attracted fluorine ion plasma (F⁻) is forbidden to enter the reaction chamber 250. On the other hand, the fluorine radical plasma (F*), which is neutral, is able to enter the reaction chamber 250. In some embodiments, when the ion plasma IO and radical plasma RD are hydrogen ion plasma (H⁺) and hydrogen radical plasma (H*), respectively, the ion filter 240 may be operated to generate a negative electrical field to attract the hydrogen ion plasma (H⁺), and thus the attracted hydrogen ion plasma (H⁺) is forbidden to enter the reaction chamber 250. On the other hand, the hydrogen radical plasma (H*), which is neutral, is able to enter the reaction chamber 250.

As shown in the figure, the source/drain regions 102SD of the channel material layers 102 are exposed to the radical plasma RD entering the reaction chamber 250. In some embodiments where the channel material layers 102 is made of oxide semiconductor material, the radical plasma RD may act as donor for the source/drain regions 102SD of the channel material layers 102. For example, when the radical plasma RD includes fluorine radical plasma (F*), the source/drain regions 102SD of the channel material layers 102 may be doped with fluorine, and thus the fluorine atomic concentration of the source/drain regions 102SD of the channel material layers 102 may be higher than the fluorine atomic concentration of the channel regions 102CH of the channel material layers 102. On the other hand, when the radical plasma RD includes hydrogen radical plasma (H*), the source/drain regions 102SD of the channel material layers 102 may be doped with hydrogen, and thus the hydrogen atomic concentration of the source/drain regions 102SD of the channel material layers 102 may be higher than the hydrogen atomic concentration of the channel regions 102CH of the channel material layers 102.

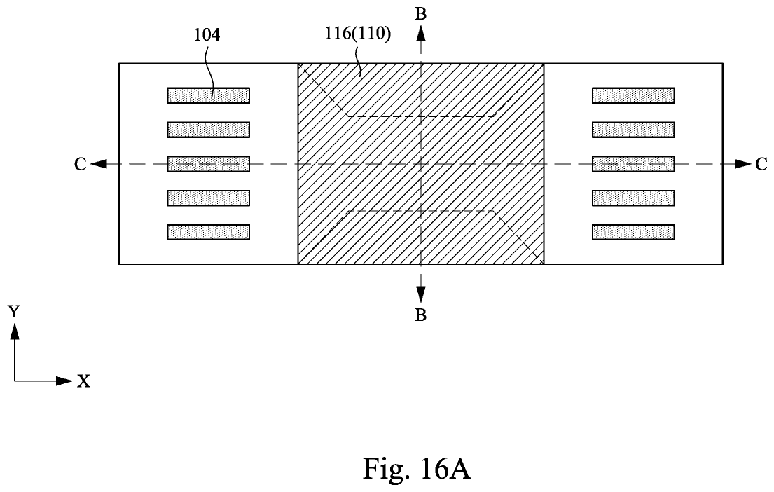

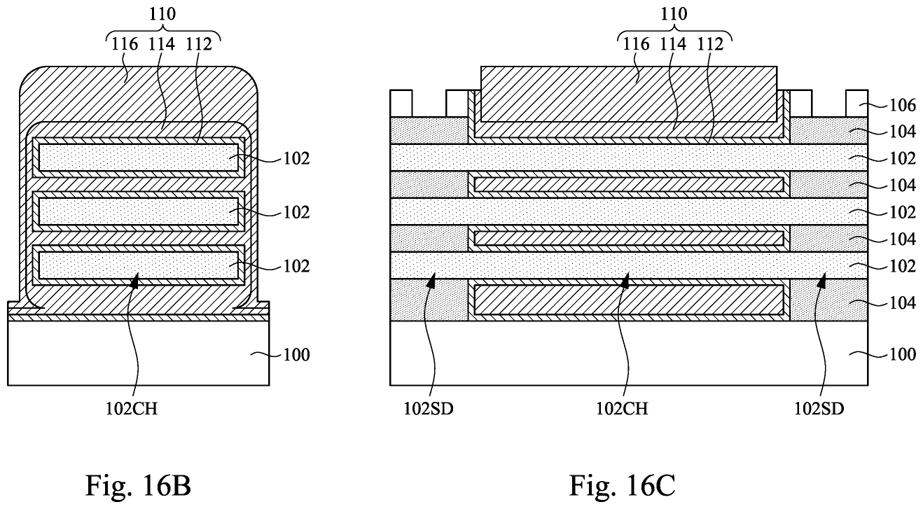

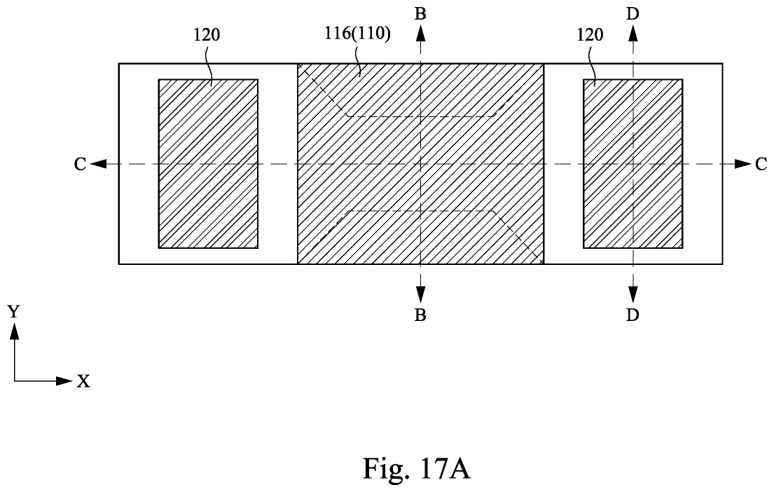

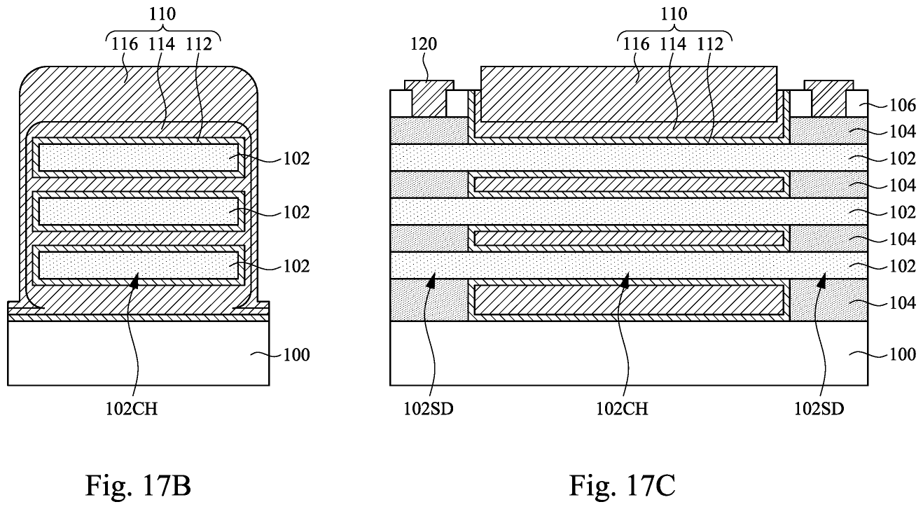

FIGS. 16A to 17C illustrate a method in various stages of forming a semiconductor device in accordance with some embodiments of the present disclosure. In greater detail, FIGS. 16A to 17A are top view of a semiconductor device. FIGS. 16B to 17B are cross-sectional views along line B-B of FIGS. 16A to 17A, respectively. FIGS. 16C to 17C are cross-sectional views along line C-C of FIGS. 16A to 17A, respectively. It is noted that some elements of FIGS. 16A to 17C are similar to those described with respect to FIGS. 1A to 14C, such elements are labeled the same and relevant details will not be repeated for brevity.

Referring back to FIGS. 12A to 12C, an etching process is performed by using the patterned mask MA4 as etching mask, so as to remove portions of the capping layer 106 that are exposed through the openings O1, and the resulting structure is shown in FIGS. 16A to 16C. Different from the embodiments shown in FIGS. 13A to 13C, in FIGS. 16A to 16C the sacrificial layers 104 remain between the source/drain regions 102SD of the channel material layers 102. In some embodiments, top surface and bottom surface of each channel material layer 102 may be in contact with respective sacrificial layers 104, while sidewalls of each channel material layer 102 may be free of coverage by the sacrificial layers 104 (see FIG. 1B).

Reference is made to FIGS. 17A to 17C. Source/drain electrodes 120 are formed over the substrate 100 and filling the openings of the capping layer 106. The source/drain electrodes 120 may be in contact with the topmost sacrificial layer 104. In some embodiments where the sacrificial layers 104 are made of conductive material such as TiN, the sacrificial layers 104 can also act as source/drain contacts, which provide electrical connection between adjacent source/drain regions 102SD of the channel material layers 102, and provide electrical connection between the source/drain regions 102SD of the channel material layers 102 and the source/drain electrodes 120.

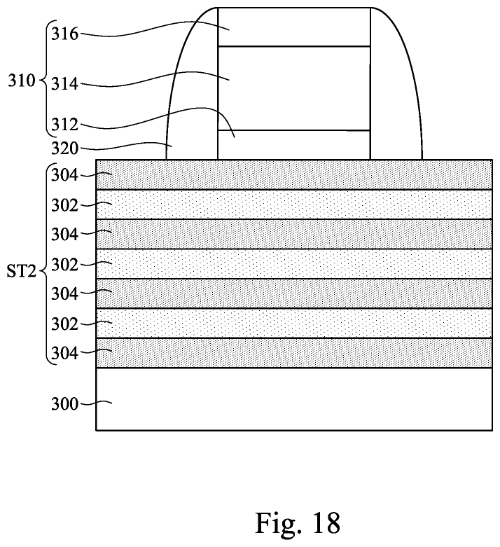

FIGS. 18 to 22 illustrate a method in various stages of forming a semiconductor device in accordance with some embodiments of the present disclosure. Although FIGS. 18 to 22 are described as a series of acts, it will be appreciated that these acts are not limiting in that the order of the acts can be altered in other embodiments, and the methods disclosed are also applicable to other structures. In other embodiments, some acts that are illustrated and/or described may be omitted in whole or in part.

Reference is made to FIG. 18. A substrate 300 is provided. A stack ST2 is formed over the substrate 300. The stack ST2 includes alternating channel material layers 302 and sacrificial layers 304. The substrate 300 may be similar to the substrate 100 as discussed above, respectively, and thus relevant details will not be repeated for brevity.

In some embodiments, the channel material layers 302 may include oxide semiconductor material, such as indium gallium zinc oxide (IGZO), indium zinc oxide (IZO), zinc oxide (ZnO), indium tin oxide (InSnO), tungsten-doped indium oxide (InWO), gallium oxide (GaOₓ), indium oxide (InOₓ), and the like. In other embodiments, the channel material layers 302 may include semiconductor material, such as silicon (Si), germanium (Ge), silicon germanium (SiGe), germanium tin (GeSn), or the like.

The sacrificial layers 304 may include material different from the material of the channel material layers 302 to provide sufficient etching selectivity. In some embodiments where the channel material layers 302 are made of oxide semiconductor material, the sacrificial layers 304 may include dielectric material, such as silicon nitride (SiN), silicon oxide (SiOₓ), or the like. In some embodiments where the channel material layers 302 are made of oxide semiconductor material, the sacrificial layers 104 may also include conductive material, such as titanium nitride (TiN). In some embodiments where the channel material layers 302 are made of semiconductor material, such as silicon or germanium, the sacrificial layers 304 may include silicon germanium (Si₁₋ₓGeₓ).

A dummy gate structure 310 is formed over and crossing the stack ST2. The dummy gate structure 310 includes a dummy gate dielectric 312, a dummy gate electrode 314 over the dummy gate dielectric 312, and a hard mask 316 over the dummy gate electrode 314. The dummy gate dielectric 312 may be, for example, silicon oxide, silicon nitride, a combination thereof, or the like, and may be deposited or thermally grown according to acceptable techniques. The dummy gate electrode 314 may be a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals. The hard mask 316 may include dielectric material, such as silicon oxide, silicon nitride, or combinations thereof.

The dummy gate structure 310 may be formed by, for example, depositing a dummy dielectric layer, a dummy gate layer, and a hard mask layer over the substrate 300, forming a patterned mask over the hard mask layer, and then performing an etching process to the dummy dielectric layer, the dummy gate layer, and the hard mask layer by using the patterned mask as etch mask.

Gate spacers 320 are formed on opposite sidewalls of the dummy gate structure 310. In some embodiments, the gate spacers 320 may be formed of silicon oxide, silicon nitride, silicon oxynitride, combinations thereof. In some embodiments, the gate spacers 320 may be formed by, for example, depositing a spacer layer blanket over the substrate, and then performing an anisotropic etching process to remove horizontal portions of the spacer layer, such that vertical portions of the spacer layer remain on sidewalls of the dummy gate structure 310.

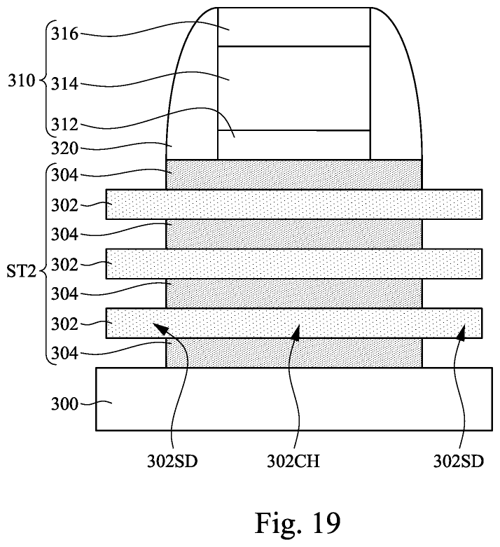

Reference is made to FIG. 19. An etching process is performed, by using the dummy gate structure 310 and the gate spacers 320 as etch mask, to remove portions of the sacrificial layers 304 that are exposed through the dummy gate structure 310 and the gate spacers 320. As a result, source/drain regions 302SD of the channel material layers 302 are suspended over the substrate 300.

After the etching process is complete. The source/drain regions 302SD may be doped to form doped regions in the source/drain regions 302SD. The doping process may be similar to the doping process as described in FIG. 15. For example, the substrate 300 including the structures formed thereon is transferred to a plasma chamber for the doping process. The plasma chamber is configured to generate ion plasma and radical plasma, while the ion plasma may be blocked by an ion filter, such that only the radical plasma may reach the substrate 300. The source/drain regions 302SD of the channel material layers 302 are exposed to the radical plasma. In some embodiments where the channel material layers 302 is made of oxide semiconductor material, the radical plasma may act as donor for the source/drain regions 302SD of the channel material layers 302. For example, when the radical plasma includes fluorine radical plasma (F*), the source/drain regions 302SD of the channel material layers 302 may be doped with fluorine, and thus the fluorine atomic concentration of the source/drain regions 302SD of the channel material layers 302 may be higher than the fluorine atomic concentration of the channel regions 302CH of the channel material layers 302. On the other hand, when the radical plasma includes hydrogen radical plasma (H*), the source/drain regions 302SD of the channel material layers 302 may be doped with hydrogen, and thus the hydrogen atomic concentration of the source/drain regions 302SD of the channel material layers 302 may be higher than the hydrogen atomic concentration of the channel regions 302CH of the channel material layers 302. In some embodiments, the doping process can be omitted.

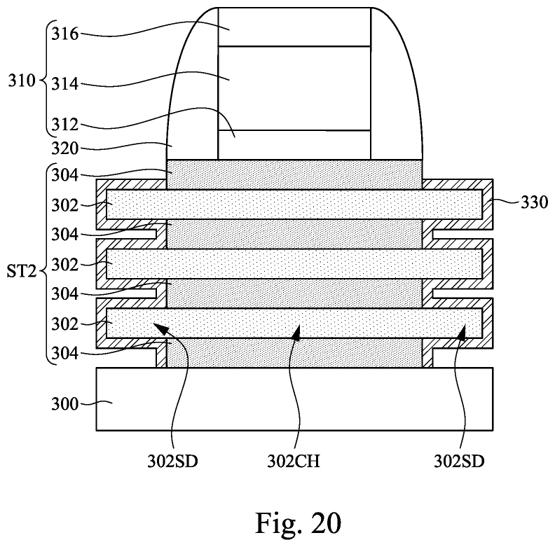

Reference is made to FIG. 20. Source/drain electrodes 330 are formed lining the exposed surfaces of the source/drain regions 302SD of the channel material layers 302. The source/drain electrodes 330 may be similar to the source/drain electrodes 120 as described above, and thus relevant details will not be repeated for brevity.

In some embodiment where the doping process discussed in FIG. 19 is omitted, a doping process may be performed to the source/drain regions 302SD of the channel material layers 302 through an oxygen scavenging process is performed, so as to increase dopant concentration in the source/drain regions 302SD of the channel material layers 302. The oxygen scavenging process may be similar to those described in FIGS. 6A to 6C. For example, the oxygen scavenging process is performed to reduce oxygen atomic concentration of the source/drain regions 302SD of the channel material layers 302, so as to generate oxygen vacancies within the source/drain regions 302SD of the channel material layers 302. In some embodiments, the oxygen vacancies can also be regarded as dopants of the source/drain regions 302SD of the channel material layers 302. In some embodiments, the dopant concentration of the source/drain regions 302SD of the channel material layers 302 is higher than the dopant concentration of the channel regions 302CH of the channel material layers 302. That is, oxygen vacancies concentration of the source/drain regions 302SD of the channel material layers 302 is higher than the oxygen vacancies concentration of the channel regions 302CH of the channel material layers 302. Stated another way, oxygen concentration of the source/drain regions 302SD of the channel material layers 302 is lower than the oxygen concentration of the channel regions 302CH of the channel material layers 302. In some embodiments, the doped source/drain regions 302SD of the channel material layers 302 can be referred to as n-type doped regions.

In some embodiments where the channel material layers 302 include oxide semiconductor material, source/drain doped regions can be formed in the source/drain regions 302SD of the channel material layers 302 using the oxygen scavenging process. The oxygen scavenging process may be performed using the source/drain electrodes 330 as oxygen scavenging layers. For example, the source/drain electrodes 330 may include a material (e.g., TiN, Ti-containing material, or the like) having higher stronger oxygen affinity than the channel material layers 302. The oxygen scavenging process can be conducted by performing an annealing process having a temperature in a range from about 25° C. to about 500° C. During the annealing process, oxygen atoms in the source/drain regions 302SD of the channel material layers 302 may be attracted by the source/drain electrodes 330, such that oxygen atoms in the source/drain regions 302SD of the channel material layers 302 may diffuse to the source/drain electrodes 330, leaving oxygen vacancies in the source/drain regions 302SD of the channel material layers 302. In some embodiments, the oxygen scavenging process as discussed in FIG. 20 may be omitted when the doping process discussed in FIG. 19 is applied.

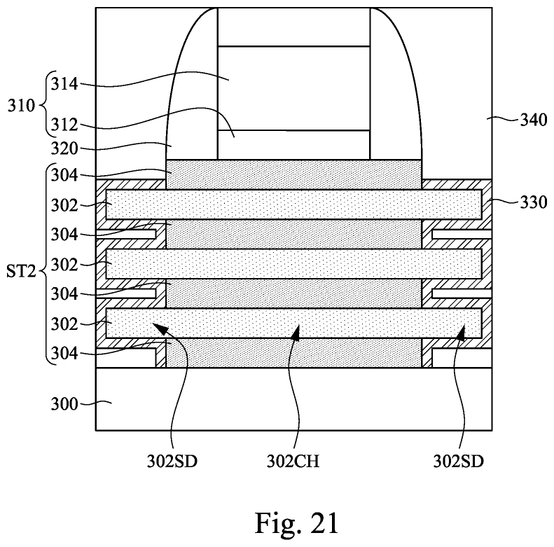

Reference is made to FIG. 21. An interlayer dielectric layer 340 is formed over the substrate 300 and covering the source/drain electrodes 330. Then, a planarization process is performed to the interlayer dielectric layer 340 until the dummy gate structure 310 is exposed. In some embodiments, the interlayer dielectric layer 340 may include silicon oxide, silicon nitride, silicon oxynitride, tetraethoxysilane (TEOS), phosphosilicate glass (PSG), borophosphosilicate glass (BPSG), low-k dielectric material, and/or other suitable dielectric materials. Examples of low-k dielectric materials include, but are not limited to, fluorinated silica glass (FSG), carbon doped silicon oxide, amorphous fluorinated carbon, parylene, bis-benzocyclobutenes (BCB), or polyimide.

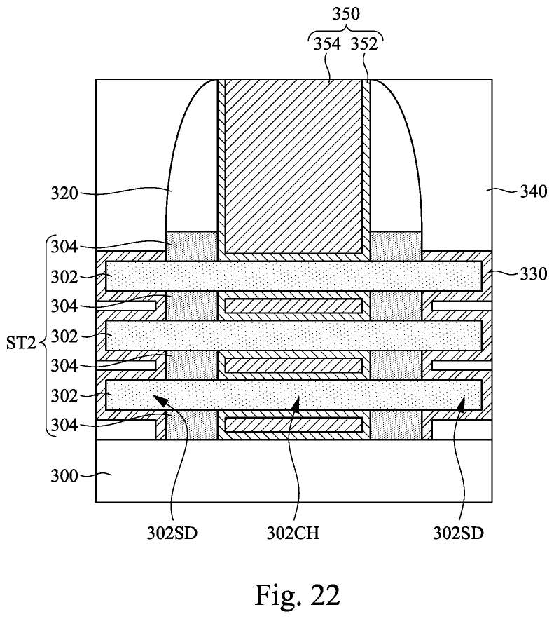

Reference is made to FIG. 22. A replacement gate (RPG) process is performed to replace the dummy gate structure 310 with a metal gate structure 350. In greater detail, a first etching process is performed to remove the dummy gate structure 310 to form a gate trench between the pair of the gate spacers 320. Afterwards, a second etching process is performed to remove portions of the sacrificial layers 304 through the gate trench, such that the channel regions 302CH of the channel material layers 302 are suspended over the substrate 300. The metal gate structure 350 is formed wrapping around each of the channel regions 302CH of the channel material layers 302.

In some embodiments, the metal gate structure 350 includes a high-k dielectric layer 352 and a gate metal 354 over the high-k dielectric layer 352. Materials of the high-k dielectric layer 352 and the gate metal 354 may be similar to those described with respect to the high-k dielectric layer 112 and the first gate metal 114 above, and thus relevant details will not be repeated for brevity.

According to the aforementioned embodiments, it can be seen that the present disclosure offers advantages in fabricating integrated circuits. It is understood, however, that other embodiments may offer additional advantages, and not all advantages are necessarily disclosed herein, and that no particular advantage is required for all embodiments. Embodiments of the present disclosure provide a gate all around (GAA) semiconductor device having an oxide semiconductor channel layer. An etching process is performed to release source/drain regions of the oxide semiconductor channel layer, and source/drain electrodes are formed wrapping around the source/drain regions of the oxide semiconductor channel layer. The source/drain electrodes may be in contact with at least four sides of the source/drain regions of the oxide semiconductor channel layer, the increased contact area will reduce the contact resistance between the source/drain electrodes and the source/drain regions of the oxide semiconductor channel layer, and will further increase the on current (ION) of the semiconductor device. Embodiments of the present disclosure provide a method for forming a gate all around (GAA) semiconductor device, in which sacrificial layers may remain in the final structure and may serve as inner spacers on opposite sidewalls of the gate structure. With such configuration, there is no need to form inner spacer by through additional deposition and lithography processes. Embodiments of the present disclosure provide a method for forming doped regions directly in the source/drain regions of the oxide semiconductor channel layer. With such configuration, there is no need to regrow source/drain epitaxy regions over the source/drain regions of the oxide semiconductor channel layer to obtain heavily-doped region.

In some embodiments of the present disclosure, a method includes forming a stack of alternating oxide semiconductor channel layers and sacrificial layers over a substrate; removing first portions of the sacrificial layers to expose channel regions of the oxide semiconductor channel layers; forming a gate structure wrapping around each of the channel regions of the oxide semiconductor channel layers; removing second portions of the sacrificial layers to expose source/drain regions of the oxide semiconductor channel layers; and forming source/drain electrodes wrapping around and in contact with each of the source/drain regions of the oxide semiconductor channel layers, wherein the source/drain electrodes are made of a metal-containing material.

In some embodiments, the sacrificial layers are made of a dielectric material.

In some embodiments, the sacrificial layers are made of a conductive material.

In some embodiments, the sacrificial layers have portions remaining on sidewalls of the gate structure after the source/drain electrodes are formed.

In some embodiments, the method further includes performing an annealing process after removing the first portions of the sacrificial layers, such that the second portions of the sacrificial layers attract oxygen atoms from the source/drain regions of the oxide semiconductor channel layers to generate oxygen vacancies in the source/drain regions of the oxide semiconductor channel layers.

In some embodiments, the method further includes performing an annealing process after forming the source/drain electrodes, such that the source/drain electrodes attract oxygen atoms from the source/drain regions of the oxide semiconductor channel layers to generate oxygen vacancies in the source/drain regions of the oxide semiconductor channel layers.

In some embodiments, the method further includes transferring the substrate to a plasma chamber; generating an ion plasma and a radical plasma through a radio frequency power source, wherein the ion plasma and the radical plasma comprises a same element; blocking the ion plasma through an ion filter, while leaving the radical plasma reaching exposed surfaces of the source/drain regions of the oxide semiconductor channel layers to form doped regions in the source/drain regions of the oxide semiconductor channel layers.

In some embodiments of the present disclosure, a method includes forming a stack of alternating oxide semiconductor channel layers and sacrificial layers over a substrate; removing first portions of the sacrificial layers to expose channel regions of the oxide semiconductor channel layers; forming a gate structure wrapping around each of the channel regions of the oxide semiconductor channel layers; and forming source/drain electrodes over the source/drain regions of the oxide semiconductor channel layers, wherein second portions of the sacrificial layers remain on sidewalls of the gate structure after the source/drain electrodes are formed.

In some embodiments, the source/drain electrodes are in contact with the second portions of a topmost one of the sacrificial layers.

In some embodiments, the method further includes removing third portions of the sacrificial layers to expose the source/drain regions of the oxide semiconductor channel layers prior to forming the source/drain electrodes, wherein the source/drain electrodes wrap around and are in contact with each of the source/drain regions of the oxide semiconductor channel layers.

In some embodiments, the source/drain electrodes are in contact with the second portions of the sacrificial layers.

In some embodiments, the sacrificial layers comprise titanium nitride (TiN).

In some embodiments, the method further includes performing an oxygen scavenging process, the oxygen scavenging process comprises using the sacrificial layers to attract oxygen atoms from the source/drain regions of the oxide semiconductor channel layers to generate oxygen vacancies in the source/drain regions of the oxide semiconductor channel layers.

In some embodiments, the method further includes performing an oxygen scavenging process, the oxygen scavenging process comprises using the source/drain electrodes to attract oxygen atoms from the source/drain regions of the oxide semiconductor channel layers to generate oxygen vacancies in the source/drain regions of the oxide semiconductor channel layers.

In some embodiments, the method further includes forming doped regions in the source/drain regions of the oxide semiconductor channel layers by exposing the source/drain regions of the oxide semiconductor channel layers to radial plasma of dopants.

In some embodiments of the present disclosure, a semiconductor device includes a substrate, oxide semiconductor channel layers, a gate structure, conductive layers, and source/drain electrodes. The oxide semiconductor channel layers are vertically stacked one above another over the substrate. The gate structure wraps around each of channel regions of the oxide semiconductor channel layers. The conductive layers are vertically stacked one above another over the substrate, in which the conductive layers are interposed between adjacent two of the oxide semiconductor channel layers. The source/drain electrodes are electrically connected to source/drain regions of the oxide semiconductor channel layers, in which the source/drain electrodes are in contact with the conductive layers.

In some embodiments, the source/drain electrodes wraps around each of the source/drain regions of the oxide semiconductor channel layers.

In some embodiments, the source/drain electrodes are spaced apart from the source/drain regions of the oxide semiconductor channel layers through the conductive layers.

In some embodiments, the conductive layers comprise titanium nitride (TiN).

In some embodiments, the source/drain electrodes are in contact with sidewalls of the conductive layers.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a stack of alternating oxide semiconductor channel layers and sacrificial layers over a substrate;
removing first portions of the sacrificial layers to expose channel regions of the oxide semiconductor channel layers;
forming a gate structure wrapping around each of the channel regions of the oxide semiconductor channel layers;
removing second portions of the sacrificial layers to expose source/drain regions of the oxide semiconductor channel layers; and
forming source/drain electrodes wrapping around and in contact with each of the source/drain regions of the oxide semiconductor channel layers, wherein the source/drain electrodes are made of a metal-containing material.

2. The method of claim 1, wherein the sacrificial layers are made of a dielectric material.

3. The method of claim 1, wherein the sacrificial layers are made of a conductive material.

4. The method of claim 1, wherein the sacrificial layers have portions remaining on sidewalls of the gate structure after the source/drain electrodes are formed.

5. The method of claim 1, further comprising performing an annealing process after removing the first portions of the sacrificial layers, such that the second portions of the sacrificial layers attract oxygen atoms from the source/drain regions of the oxide semiconductor channel layers to generate oxygen vacancies in the source/drain regions of the oxide semiconductor channel layers.

6. The method of claim 1, further comprising performing an annealing process after forming the source/drain electrodes, such that the source/drain electrodes attract oxygen atoms from the source/drain regions of the oxide semiconductor channel layers to generate oxygen vacancies in the source/drain regions of the oxide semiconductor channel layers.

7. The method of claim 1, further comprising:
transferring the substrate to a plasma chamber;
generating an ion plasma and a radical plasma through a radio frequency power source, wherein the ion plasma and the radical plasma comprises a same element; and
blocking the ion plasma through an ion filter, while leaving the radical plasma reaching exposed surfaces of the source/drain regions of the oxide semiconductor channel layers to form doped regions in the source/drain regions of the oxide semiconductor channel layers.

8. A method, comprising:
forming a stack of alternating oxide semiconductor channel layers and sacrificial layers over a substrate;
removing first portions of the sacrificial layers to expose channel regions of the oxide semiconductor channel layers;
forming a gate structure wrapping around each of the channel regions of the oxide semiconductor channel layers; and
forming source/drain electrodes over source/drain regions of the oxide semiconductor channel layers, wherein second portions of the sacrificial layers remain on sidewalls of the gate structure after the source/drain electrodes are formed.

9. The method of claim 8, wherein the source/drain electrodes are in contact with the second portions of a topmost one of the sacrificial layers.

10. The method of claim 8, further comprising:
removing third portions of the sacrificial layers to expose the source/drain regions of the oxide semiconductor channel layers prior to forming the source/drain electrodes, wherein the source/drain electrodes wrap around and are in contact with each of the source/drain regions of the oxide semiconductor channel layers.

11. The method of claim 10, wherein the source/drain electrodes are in contact with the second portions of the sacrificial layers.

12. The method of claim 8, wherein the sacrificial layers comprise titanium nitride (TiN).

13. The method of claim 8, further comprising performing an oxygen scavenging process, the oxygen scavenging process comprises using the sacrificial layers to attract oxygen atoms from the source/drain regions of the oxide semiconductor channel layers to generate oxygen vacancies in the source/drain regions of the oxide semiconductor channel layers.

14. The method of claim 8, further comprising performing an oxygen scavenging process, the oxygen scavenging process comprises using the source/drain electrodes to attract oxygen atoms from the source/drain regions of the oxide semiconductor channel layers to generate oxygen vacancies in the source/drain regions of the oxide semiconductor channel layers.

15. The method of claim 8, further comprising forming doped regions in the source/drain regions of the oxide semiconductor channel layers by exposing the source/drain regions of the oxide semiconductor channel layers to radial plasma of dopants.

16. A semiconductor device, comprising:
a substrate;
oxide semiconductor channel layers vertically stacked one above another over the substrate;
a gate structure wrapping around each of channel regions of the oxide semiconductor channel layers;
conductive layers vertically stacked one above another over the substrate, wherein the conductive layers are interposed between adjacent two of the oxide semiconductor channel layers; and
source/drain electrodes electrically connected to source/drain regions of the oxide semiconductor channel layers, wherein the source/drain electrodes are in contact with the conductive layers.

17. The semiconductor device of claim 16, wherein the source/drain electrodes wraps around each of the source/drain regions of the oxide semiconductor channel layers.

18. The semiconductor device of claim 16, wherein the source/drain electrodes are spaced apart from the source/drain regions of the oxide semiconductor channel layers through the conductive layers.

19. The semiconductor device of claim 16, wherein the conductive layers comprise titanium nitride (TiN).

20. The semiconductor device of claim 16, wherein the source/drain electrodes are in contact with sidewalls of the conductive layers.
